(19) United States
(12) Patent Application Publication
(10) Pub. No.: US 2024/0388190 A1
(43) Pub. Date: Nov. 21, 2024

(54) ELECTRIC DYNAMIC POWER CONVERSION SYSTEM

(71) Applicant: FTEX INC., Montreal (CA)

(72) Inventor: Alexandre Cosneau, Montreal (CA)

(73) Assignee: FTEX INC., Montreal, QC (CA)

(21) Appl. No.: 18/694,446

(22) PCT Filed: Sep. 23, 2022
(86) PCT No.: PCT/IB2022/059049

§ 371 Date: Mar. 22, 2024

Related U.S. Application Data
(60) Provisional application No. 63/261,513, filed on Sep. 23, 2021.

(51) Int. Cl. H02M 1/00; B60L 15/04; H02M 7/5387

(52) U.S. Cl. CPC H02M 1/007; B60L 15/04; H02M 1/0025; H02M 1/0054; H02M 7/53871; B60L 2210/10; B60L 2210/40; B60L 2240/525

(57) ABSTRACT

There is provided an electric dynamic drive train for electric vehicles (EVs), the electric dynamic drive train including a high frequency direct current (DC)-DC converter and a DC-alternative current (AC) inverter. The high frequency DC-DC power converter includes a DC-DC controller connected to one or more core cells comprising a driver, a half-bridge connected to the driver, the half-bridge including high and low sides transistors in thermal contact with a cooling system including a heat spreader, an inductor and a capacitor connected to the half-bridge and a capacitor connected to the inductor. The high frequency DC-DC power converter enables having an almost instantaneous response time by reducing voltage drops between transients, enables generating a clean waveform signal improving the longevity of connected components, and enables the inverter and the motor in the EVs to be sized apart from one to another.

### CROSS-REFERENCE TO RELATED APPLICATIONS

The present application claims priority to U.S. Provisional Patent Application Ser. No. 63/261,513 filed on Sep. 23, 2021, the content of which is incorporated herein by reference in its entirety.

### FIELD

The present technology relates to an electric dynamic power conversion system for driving an electric motor, such as an electric motor of an electric vehicle.

### BACKGROUND

Electromechanical energy converters are known in the art, such as the electric motor 106 used in the prior art power train system 100 illustrated in FIG. 1. Such electromechanical energy converters are adapted for electrical vehicle (EV) motors, where electrical power from a battery 102 is converted and transmitted to an electro-mechanical motor 106 by means of an inverter 104.

A user or software 108 controls the EV by means of software and hardware components (not illustrated) in response to different driving conditions. For instance, when the user or software 108 varies the speed of an EV from a stopped state to a moving state (e.g., via a user interface connected to the power train system 100), the need in torque for accelerating and maintaining the vehicle at a given speed varies, and the inverter 104 controls the rotation per minute (rpm) of the motor 106 accordingly, usually at a cost of electrical power efficiency. For example, the user or software 108 may provide instructions to the inverter 104, thereby forcing a defined rpm of the motor 106 for a given torque.

The battery 102 is operable to provide a direct current (DC) to the inverter 104. For example, the battery 102 provided in the form of battery pack composed of a plurality of individual cells, the battery being configured to store and provide high amounts of energies (e.g., kilowatt-hours) for operating a system, such as an EV. It will be appreciated that the battery 102 may be provided in various sizes, shapes and energy capacity depending on the application and type of vehicle.

As mentioned above, the inverter 104 defines the rpm of the motor 106, by providing an alternative current (AC) signal of a corresponding frequency thereto. For example, to modulate the frequency of the AC signal transmitted to the motor 106, the inverter 104 includes control and feedback circuitry to transform the input DC signal provided by the battery 102 into an AC signal. It will be appreciated that a motor controller, an electronic speed controller, an inverter, a motor controller/inverter and a motor drive altogether refer to the same element of an EV.

It will be appreciated that an electric motor 106, also known as traction motor, works similarly to other electrical motors used in different applications, where a rotor attached to a shaft rotates about an axis concentrical to the center of a stator, which provides a rotative motion to the rotor by means of electromagnetic force. In the case of the electric motor 106, the speed of the rotor is proportional to the frequency of the AC signal circulating in the stator. Thus, the frequency of the AC signal provided by the motor controller/inverter 104 is proportional to the rpm of the motor 106.

The DC-link (not numbered in FIG. 1) is the electrical connection between the battery 102 and the inverter 104, and its voltage is the maximum voltage reference of the power train system 100. EVs on the market generally share a unique DC-link voltage, where the battery 102, the inverter 104 and the maximum phase voltage of the electric motor 106 are equal, which simplifies the electrical architecture of the power train system 100. Some models of EVs have DC-link voltages around the range of 400 volts, while incoming EV systems will have DC-link voltages around 800 volts. These high voltages will enable to reduce the charging time of the battery 102 because more power may be transferred in less time (i.e., less current is needed to transfer the same power compared to a battery with less voltage) and will enable to use smaller electric cables that are cheaper and easier to manufacture.

However, some issues remain with high-voltage DC links, as driving the electric motor 106 with higher voltages at lower speeds and lower torques will increase power switching losses in the electric motor 106 and the inverter 104.

### SUMMARY

It is an object of the present technology to ameliorate at least some of the inconveniences present in the prior art. One or more embodiments of the present technology may provide and/or broaden the scope of approaches to and/or methods of achieving the aims and objects of the present technology.

One or more embodiments of the present technology have been developed based on developer's appreciation that while increasing the DC-link voltage in a power train system has advantages, it will also increase power losses and decrease the performance of the electric motor and inverter, as a non-limiting example via power switching losses in the inverter, conduction losses, diode losses in the inverter and copper/winding and iron losses in the EV motor, and render the power train system at lower speed, lower torques and/or lower power usage. It will be appreciated that power train system refers to the dynamic drive train when connected to the motor and energy source.

Developers of the present technology propose integrating a high frequency DC-DC power converter in the power train system between the energy source and the inverter, which will enable to scale and control the DC-link voltage according to various motor load conditions and improve the overall efficiency of the power train system. The architecture of such a dynamic drive train system comprising the high frequency DC-DC converter and adapted inverter will enable the power train system to benefit from the advantages of the high voltage energy sources without suffering from at least some of the aforementioned drawbacks.

One or more embodiments of the present technology provide efficiency and control advantages compared to conventional power trains without DC-DC converters.

One or more embodiments of the present technology enable reducing constraints on the design of the energy source in the form of a battery, for example by boosting the DC voltage when the battery voltage varies due to a reduction of its state of charge (SoC), which require electric motors to be designed accordingly (e.g., by scaling the number of winding turns in the electric motor to compensate for the reduction of the battery SoC), which in turn diminishes the ability of the electric motor to meet the torque and power requirements during high-speed operation and in the maximum constant power curve of the electric motor. One or more embodiments of the present technology will enable to extend the lifespan of the electric motor and its ability to meet torque and power requirements during the low battery SoC, while also simplifying the design of the electric motor and its cost.

Further, one or more embodiments of the present technology will enable facilitating the design and sizing of the battery and/or electric motor in a power train of an EV, while also being adaptable to different types of electric vehicles and/or applications.

One or more embodiments of the present technology provide an architecture for a dynamic drive train comprising a high-frequency dynamic bi-directional DC-DC converter and corresponding inverter which function synergistically to increase real-time and safety requirements in power train systems and EVs, and where the DC-DC voltage and current control loops are synchronized with the torque command and modulation ratio to ensure optimal efficiency of the high-frequency DC-DC converter, inverter and electric motor and limit noise vibration harshness (NVH) of the power train system. One or more embodiments of the present technology provide an architecture that minimizes dynamic DC-DC losses, which could cancel the efficiency gains of a variable voltage EV motor.

One or more embodiments of the present technology provide an architecture for a high frequency DC-DC power converter which may be used with, but not limited to Gallium-Nitride (GaN) transistors with corresponding drivers, which enable the DC-DC power converter to operate at high frequencies and low response time with power levels that are optimal for EV power ranges. One or more embodiments of the present technology provide at least some of the aforementioned benefits via the architecture of the high frequency DC-DC power converter, which includes the selection and placement of its components, as well as the use of an efficient thermal solution to optimize their performance. In one or more embodiments, a corresponding DC-AC inverter may be used to provide an output AC signal to the electric motor having the cleanest waveform possible without increasing the frequency of the AC signal. In one or more embodiments, an electronic control unit in the form of hardware and/or software components is provided with the high-frequency DC-DC converter and the DC-AC inverter to receive and control the required inputs and/or outputs thereof and to optimize their efficiency.

Thus, one or more embodiments of the present technology are directed to an electric dynamic power conversion system.

In accordance with a broad aspect of the present technology, there is provided a dynamic drive train for an electric vehicle comprises: a high frequency direct current (DC)-DC power converter electrically connectable to an energy source to receive an input DC signal therefrom. The high frequency DC-DC power converter comprises: at least one single arm switching power converter, comprises: a half-bridge electrically connectable to the energy source, the half-bridge being in thermal contact with a cooling system comprises a heat spreader, an inductor electrically connected to the half-bridge, and at least one capacitor electrically connected parallel to the inductor, a driver, a DC-DC controller operatively connected to the driver. The DC-DC controller is configured to: receive an indication of a required power output, receive an indication of the input DC signal, and generate, based on the indication of the input DC signal and the indication of the required power output, a pulse-width modulated (PWM) signal, and transmit the PWM signal to the driver. The driver is configured to: receive the PWM signal from the DC-DC controller, generate, based on the PWM signal, a control signal, and transmit the control signal to the half-bridge, the control signal causing the half-bridge to convert the input DC signal into a switched DC signal transmitted to the inductor and the at least one capacitor to obtain an output DC signal, the output DC signal having the required power output, and a DC-alternative current (AC) inverter electrically connected to the high frequency DC-DC power converter to receive the output DC signal therefrom, the DC-AC inverter being electrically connectable to an electric motor, the DC-AC inverter being configured to: receive an indication of a required inverter output, and convert, based on the indication of the required inverter output and the indication the output DC signal, the output DC signal into an output AC signal.

In one or more embodiments of the dynamic drive train, the indication of the required inverter output comprises at least one of a required speed and required torque.

In one or more embodiments, the indication of the required inverter output comprises parameters of a required output AC signal.

In one or more embodiments of the dynamic drive train, the dynamic drive train further comprises: a first DC bus having an input electrically connectable to the energy source and being electrically connected to the half-bridge, a second DC bus electrically connected to the inductor and the capacitor and to the DC-AC inverter, and an AC bus electrically connected to the DC-AC inverter and having an output electrically connectable to the electric motor.

In one or more embodiments of the dynamic drive train, the dynamic drive train further comprises a first power sensor electrically connected to the first DC bus and to the at least one single arm switching power converter, the first power sensor being configured to: measure the input DC signal to obtain the indication of the input DC signal, and transmit the indication of the input DC signal to the DC-DC controller.

In one or more embodiments of the dynamic drive train, the half-bridge comprises a first half-bridge, the driver comprises a first driver, the PWM signal comprises a first PWM signal, and the control signal comprises a first control signal, and the DC-AC inverter comprises: a DC-AC controller configured to: receive the indication of the required inverter output, receive an indication of the output DC signal, and generate, based on the indication of the output DC signal and the indication of the required inverter output, a second PWM signal, and at least one single arm switching power inverter, comprises: a second half-bridge electrically connected to the second DC bus and the AC bus, and a second driver electrically connected to the DC-AC controller, the second driver being configured to: receive the second PWM signal from the DC-AC controller, and transmit the second control signal to the second half-bridge, the second control signal causing the second half-bridge to convert the output DC signal into the output AC signal.

In one or more embodiments of the dynamic drive train, the second half-bridge is in thermal contact with a second cooling system comprising a second heat-spreader.

In one or more embodiments of the dynamic drive train, the dynamic drive train further comprises a second power sensor electrically connected to the second DC bus and to the AC bus, the second power sensor being configured to: measure the output DC signal to obtain the indication of the output DC signal, and transmit the indication of the output DC signal to the DC-AC controller for generating the second PWM signal.

In one or more embodiments of the dynamic drive train, the dynamic drive train further comprises a third power sensor electrically connected to the second DC bus between the first half-bridge and the first inductor, the third power sensor being configured to: measure the switched DC signal to obtain an indication of the output switched DC signal, and transmit an indication of the output switched DC signal to the DC-DC controller for generating the first PWM signal.

In one or more embodiments of the dynamic drive train, the dynamic drive train further comprises: a fourth power sensor electrically connected to the AC bus downstream the second half-bridge, the third power sensor being configured to: measure the output AC signal to obtain an indication of the output AC signal, and transmit an indication of the output AC signal to the DC-AC controller for generating the second PWM signal.

In one or more embodiments of the dynamic drive train, the first half-bridge comprises a first high side transistor and a first low side transistor, and the first driver is configured to selectively activate one of the first high side transistor and the first low side transistor based on the first control signal to obtain the switched DC signal, and In one or more embodiments of the dynamic drive train: the second half-bridge comprises a second high side transistor and a second low side transistor, and the second driver is configured to selectively activate one of the second high side transistor and the second low side transistor based on the second control signal to obtain the output AC signal.

In one or more embodiments of the dynamic drive train, the inductor is configured to smooth a current waveform of the switched DC signal, and the at least one capacitor is configured to smooth a voltage waveform of the switched DC signal to obtain the output DC signal.

In one or more embodiments of the dynamic drive train, the dynamic drive train further comprises an electronic control unit operatively connected to the DC-AC controller, the electronic control unit being configured to: determine and transmit the indication of a required power output to the DC/DC controller, and determine and transmit the indication of the required inverter output to the DC-AC controller.

In one or more embodiments of the dynamic drive train, at least one of the first high side transistor and the first low side transistor comprises at least one of: a bipolar junction transistor (BJT), a field-effect transistors (FET), a metal-oxide-semiconductor field-effect transistor (MOSFET), and an insulated gate bipolar transistors (IGBT).

In one or more embodiments of the dynamic drive train, at least one of the first high side transistor and the first low side transistor comprises a gallium-nitride (GaN) transistor.

In one or more embodiments of the dynamic drive train, the first high side transistor and the first low side transistor are configured in a top-cooled arrangement with the heat spreader.

In one or more embodiments of the dynamic drive train, the cooling system further comprises a heat sink fixed onto a surface of the heat spreader.

In one or more embodiments of the dynamic drive train, the heat sink is fixed on the surface of the heat spreader using a thermal paste.

In one or more embodiments of the dynamic drive train, the heat sink is soldered onto a surface of the heat spreader.

In one or more embodiments of the dynamic drive train, the first cooling system is configured to maintain the first high side transistor and the first low side transistor at an operating temperature of about 80 degrees Celsius.

In one or more embodiments of the dynamic drive train, the first driver is configured to operate at a first driver voltage, and the first half-bridge is configured to operate at a first bridge voltage, the first driver voltage being at least twice the first bridge voltage.

In one or more embodiments of the dynamic drive train, the at least one single arm switching power converter comprises a plurality single arm switching power converters configured in phase interleave.

In one or more embodiments of the dynamic drive train, the at least one single arm switching power inverter comprises a plurality of single arm switching power inverter configured to provide the output AC signal, the output AC signal being a multi-phase AC signal.

In one or more embodiments of the dynamic drive train, a second number of the plurality of single arm switching power inverter is proportional to a first number of the plurality of single arm switching power converter.

In one or more embodiments of the dynamic drive train, a first power range of operation of the high frequency DC-DC power converter is equal to a second power range of operation of the DC-AC inverter.

In one or more embodiments of the dynamic drive train, the high frequency DC-DC power converter is configured to operate at frequencies between 500 kHz and 100 MHz.

In one or more embodiments of the dynamic drive train, high frequency DC-DC power converter is configured to operate at a power range between 250 W to 5 kW.

In one or more embodiments of the dynamic drive train, the dynamic drive train further comprises: a first set of capacitors electrically connected to the first DC bus and to the half-bridge in the DC-DC power converter, and a second set of capacitors electrically connected to the first set of capacitors and the half-bridge, the first set of capacitors and the second set of capacitors are configured to smooth transients in the input DC signal.

In one or more embodiments of the dynamic drive train, the dynamic drive train is implemented on at least one printed circuit board (PCB).

In accordance with a broad aspect of the present technology, there is provided a dynamic drive train for an electric vehicle comprising: a control unit, a high frequency direct current (DC)-DC power converter electrically connectable to an energy source to receive an input DC signal therefrom, the high frequency DC-DC power converter comprising: a first DC bus, an input of the first DC bus being electrically connectable to the energy source, a second DC bus, at least one single arm switching power converter, comprising: a half-bridge electrically connected to the first DC bus and the second DC bus, the half-bridge being in thermal contact with a cooling system comprising a heat spreader, an inductor electrically connected to the half-bridge and the second DC bus, and at least one capacitor electrically connected parallel to the inductor and to the second DC bus, and a driver, a DC-DC controller operatively connected to the driver and the control unit, the DC-DC controller is configured to: receive an indication of a required power output from the control unit, receive an indication of the input DC signal, and generate, based on the indication of the input DC signal and the indication of the required power output, a pulse-width modulated (PWM) signal, and transmit the PWM signal to the driver, and the driver is configured to: receive the PWM signal from the DC-DC controller, generate, based on the PWM signal, a control signal, and transmit the control signal to the half-bridge, the control signal causing the half-bridge to convert the input DC signal into a switched DC signal transmitted to the inductor and the at least one capacitor to obtain an output DC signal, the output DC signal having the required power output, and a DC-alternative current (AC) inverter electrically connected to the second DC bus to receive the output DC signal therefrom, the DC-AC inverter being electrically connectable to an electric motor, the DC-AC inverter being configured to: receive an indication of a required inverter output from the control unit, and convert, based on the indication of the required inverter output and the indication the output DC signal, the output DC signal into an output AC signal.

In one or more embodiments of the dynamic drive train, the half-bridge comprises a high-side transistor and low-side transistor.

In one or more embodiments of the dynamic drive train, the high side transistor and the low side transistor each comprise a respective gallium-nitride (GaN) transistor.

In one or more embodiments of the dynamic drive train, the high frequency DC-DC power converter is configured to operate at frequencies between 500 kHz and 100 MHz.

In one or more embodiments of the dynamic drive train, the high frequency DC-DC power converter is configured to operate at a power range between 250 W to 5 kW.

### Terms and Definitions

In the context of the present specification, the words “first”, “second”, “third”, etc. have been used as adjectives only for the purpose of allowing for distinction between the nouns that they modify from one another, and not for the purpose of describing any particular relationship between those nouns. Thus, for example, it should be understood that, the use of the terms “first component” and “third component” is not intended to imply any particular order, type, chronology, hierarchy or ranking (for example) of/between the components, nor is their use (by itself) intended imply that any “second component” must necessarily exist in any given situation. Further, as is discussed herein in other contexts, reference to a “first” element and a “second” element does not preclude the two elements from being the same actual real-world element. Thus, for example, in some instances, a “first” component and a “second” component may be the same software and/or hardware, in other cases they may be different software and/or hardware.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a schematic diagram of a prior art power train system for electric vehicles (EVs).

FIG. 2 illustrates a schematic diagram of an energy source, a dynamic drive train and a motor interacting with a user and an environment in accordance with one or more non-limiting embodiments of the present technology.

FIG. 3 illustrates a schematic diagram of the DC-DC power converter of FIG. 2 in accordance with one or more non-limiting embodiments of the present technology.

FIG. 4 illustrates a schematic diagram of the DC-AC inverter of FIG. 2 in accordance with one or more non-limiting embodiments of the present technology.

FIG. 5 illustrates a schematic diagram of a single arm switching power converter in accordance with one or more non-limiting embodiments of the present technology.

FIG. 6 illustrates a schematic diagram of the half-bridge in the single arm switching power converter of FIG. 5 in accordance with one or more non-limiting embodiments of the present technology.

FIG. 7 illustrates a graph of a voltage signal (y-axis) as a function of time (x-axis) resulting from activation of the high side transistor and the low side transistor in the half bridge of FIG. 6 in accordance with one or more non-limiting embodiments of the present technology.

FIG. 8A, FIG. 8B and FIG. 8C illustrate respectively a side view, a bottom perspective view and a top perspective view of the half-bridge and the single arm switching power converter of the DC-DC power converter of FIG. 2 implemented on a printed circuit board (PCB) in accordance with one or more non-limiting embodiments of the present technology.

FIG. 9A and FIG. 9B illustrate respectively a side view of the support loop of the DC-DC power converter on a PCB and a side view of the main decoupling loop of the DC-DC power converter on the PCB with the core loop removed in accordance with one or more non-limiting embodiments of the present technology.

FIG. 10A, FIG. 10B, FIG. 10C and FIG. 10D illustrate respectively a bottom view and a top view of the DC-DC power converter on the PCB, and a bottom view and a top view of a single arm switching power converter removed from the DC-DC power converter on the PCB in accordance with one or more non-limiting embodiments of the present technology.

FIG. 11A, FIG. 11B and FIG. 11C illustrate respectively a side view, a bottom view and a top view of the single arm switching power converter on a PCB in accordance with one or more non-limiting embodiments of the present technology.

FIG. 12 illustrates a perspective view of a heat spreader fixed on a half-bridge on a PCB in accordance with one or more non-limiting embodiments of the present technology.

FIG. 13 illustrates a top view of a DC-DC power converter on a PCB in accordance with one or more non-limiting embodiments of the present technology.

FIG. 14 illustrates a top view of a dynamic drive train on a PCB, the dynamic drive train being electrically connected to battery cells and to an electric motor in accordance with one or more non-limiting embodiments of the present technology.

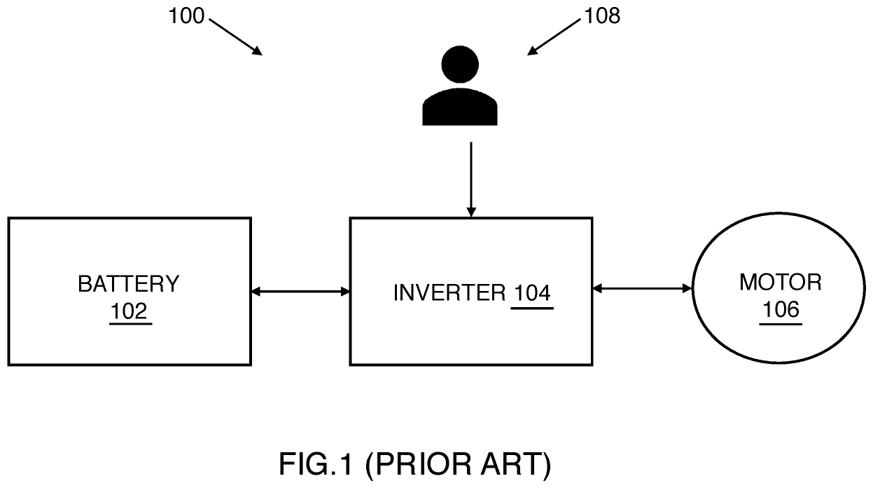

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology.

Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

With these fundamentals in place, we will now consider some non-limiting examples to illustrate various implementations of aspects of the present technology.

One or more embodiments of the present technology are directed towards adding design flexibility to power train systems and minimizing compromises in system performances of electromechanical energy converters in EVs. By placing a high-frequency power converter between the energy source (e.g., a battery, fuel cell, etc.) and the inverter, one or more embodiments of the present technology enable the inverter and the motor to be sized apart from one to another. The high frequency power converter receives direct current (DC) input signals from the energy source (e.g., battery, fuel cell, nuclear energy, etc.), which may not be constant due to drop in voltages over its discharge, and provides the DC input signals to a DC bus with variables properties (i.e., high or low voltage) to output DC signals with different voltages. By using a DC-DC controller configured to change the DC bus voltage proprieties, the high-frequency DC-DC power converter enables generating a wide range of voltages and currents output in order to match the demand of the motor drive.

One or more embodiments of the high frequency DC-DC power converter of the present technology enable reducing the form factor of an electrical power train system, as well as having an almost instantaneous response time (i.e., no lag or voltage drop between transients) compared to conventional electrical power trains.

Thus, in one or more embodiments of the present technology, the energy source (e.g., battery) may be sized in the power train system according to mechanical constraints, without having to comply with the required power input of the motor, and vice versa, as would be the case of a system without a power converter. Indeed, power train sizing depends on the battery and the motor requirements. It is complex due to the characteristics of the systems that both transform energy in a different way (electro chemically for the battery, electromotive force for the motor). On top of that, mechanical constraints are applied to the sizing characteristics for everything to fit in a very confined space.

These sizing constraints and the different nature of these systems comes with compromises that must be done, usually to the detriment of performance and/or range. One or more embodiments of the present technology provide a high frequency DC-DC power converter that acts as a sizing buffer. In one or more embodiments, the energy source may be a battery in the form of a battery pack and may be optimized by having a lower internal resistance, thus minimizing the heating of the pack by having fewer cells in series. In one or more other embodiments, the motor may be designed to operate on higher voltages depending on the application to provide more speed, while being coupled to a low-voltage battery.

One or more embodiments of the present technology provide a bi-directional dynamic drive train. Generally, a dynamic drive train is used to convert DC electrical energy received from a battery into AC energy by providing rotative motion to a shaft to power a motor (e.g., motor of an EV). One or more embodiments of the present technology can be used in reverse as a power conversion unit, where AC electrical energy from an outlet may be converted into DC electrical energy and used to charge a power bank, as a non-limiting example.

### Dynamic Drive Train

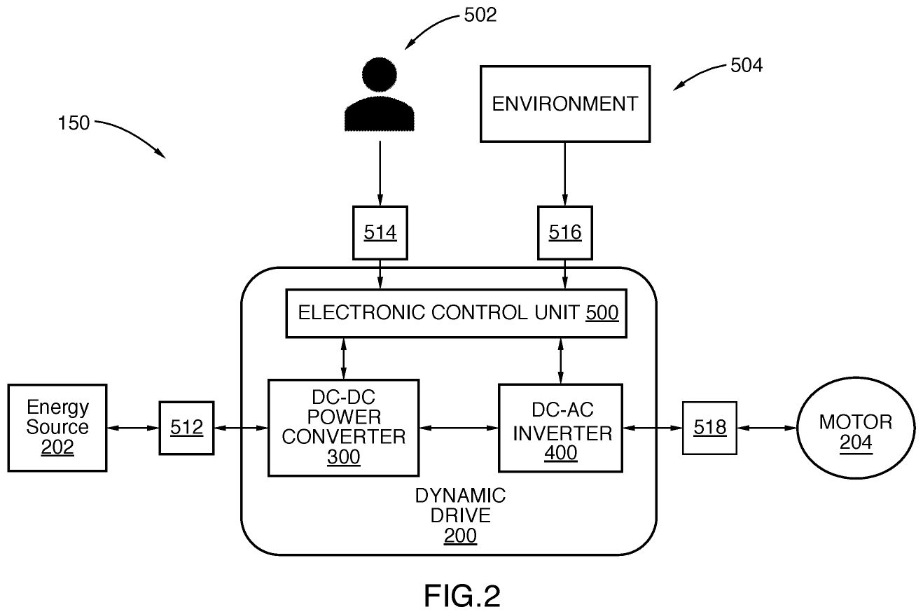

FIG. 2 illustrates a schematic diagram of a power train system 200 interacting with a user 502 and an environment 504, the power train system 150 being illustrated in accordance with one or more non-limiting embodiments of the present technology.

The power train system 150 comprises inter alia an energy source 202, a dynamic drive train 200 and a motor 204 electrically connected to each other.

The energy source 202 provides DC electrical power to the dynamic drive train 200, which converts the DC electrical power into AC electrical power and provides the AC electrical power to the motor 204. The energy source 202 may be for example a battery in the form of a battery pack. As a non-limiting example, the battery pack may be a lithium-ion battery pack. Other non-limiting examples of battery packs include lead-acid battery packs, nickel-cadmium battery packs, nickel-metal hydride battery packs, and sodium nickel chloride (“zebra”) battery packs.

The user 502 may operate an electric vehicle comprising the power train system 150, where the power train system 150 receives feedback from the environment 504. It will be appreciated that the user 502 may provide instructions to the power train system 200 via a user interface (not illustrated) in the operatively connected to the power train system 200. In the context of the present technology, the user 502 may be a human user or may be implemented as a combination of hardware and software, for example as an autonomous driving system.

As a non-limiting example, in embodiments where the power train system 200 is implemented within an electric vehicle, the user 502 may provide the power train system 200 with torque requirements such as a given spontaneous acceleration or a given speed via the in response to several driving conditions in the environment 504. The power train system 150 may acquire parameters from and send feedback to the user 502 via a first interface 514 and the receive feedback from the environment via second interface 516.

The motor 204 is configured to receive the AC electrical energy from the dynamic drive train 200 and to convert the electrical energy into mechanical energy to move the vehicle. The dynamic drive train 200 receives DC electrical energy from the energy source via third interface 512, which may be an electrical connection such as a DC bus.

The dynamic drive train 200 is configured to deliver required power to the motor 204 via fourth interface 518 to control the vehicle comprising the power train system 150.

The dynamic drive train 200 comprises inter alia a DC-DC power converter 300, a DC-AC inverter 400 and an electronic control unit 500.

The DC-DC power converter 300 is electrically connected to the energy source 202, to the DC-AC inverter 400 and to the electronic control unit 500.

The DC-DC power converter 300 is configured to inter alia: (i) receive DC electrical power from the energy source 202; and (ii) provide converted DC power to the DC-AC inverter 400. The DC-DC power converter 300 is a high-frequency power converter configured to inter alia generate a wide range of voltages and DC signals output to match the power demand of the DC-AC inverter 400 and according to instructions provided by the electronic control unit 500. In other words, the DC-DC power converter 300 adapts the voltage of the electrical power delivered from the energy source 202 to match the voltage of the motor 204 and the power demand via the inverter 400.

In some alternative embodiments, the DC-DC power converter 300 is further configured to distribute electrical power to different components (e.g., wipers, lights, infotainment system, mirror control, set heaters, etc.) (not illustrated) of the electric vehicle by converting DC power output by the energy source 202 and providing the converted DC power to the components depending on the requirements of the components.

The DC-DC power converter 300 is configured to operate at high frequencies (e.g., between 500 kHz and 100 MHz), which enables reducing its size and enables having an almost instantaneous response time by reducing “lag” or voltage drops between transients as well as generating a clean waveform signal that is beneficial for the longevity of the connected components. It will be appreciated that since the DC-DC power converter 300 is part of the motion power flow of the power train system, a short voltage response time enables to satisfy the torque response time of the power train system 150 and ensures the quality of the control of the inverter 400 and the electric motor 204. Thus, by operating at high frequencies (e.g., between 500 kHz and 100 MHz), the DC-DC power converter 300 provides a short response time (e.g., between 10 and 20 microseconds). In the context of the present technology, the DC-DC power converter 300 is configured to act as an energy converter and as an energy buffer, for example if used in an electric source hybrid condition, as will be explained in more detail herein below.

The DC-AC inverter 400, also known as inverter, electronic speed controller (ESC), drive or perfect waveform inverter, is electrically connected to the DC-DC power converter 300, to the motor 204 and to the electronic control unit 500.

The DC-AC inverter 400 is configured to inter alia: (i) receive the converted DC signal from the DC-DC power converter 300; (ii) receive control signals from the electronic control unit 500; and (iii) generate, based on the control signals and the converted DC signal, a multi-phase AC signal to control the motor 204.

The DC-AC inverter 400 is configured to convert DC power (i.e. DC electrical signals) into AC power (i.e., AC electrical signal) with a lower path resistance so as to drive the electric motor 204 at a desired reference (i.e., speed or torque). In the context of the present technology, the DC-AC inverter 400 is configured to provide a near-perfect AC power waveform to the motor 204, which enables improving the efficiency of the dynamic drive train 200 and saving energy by inter alia generating less harmonics. It will be appreciated that harmonics are a source of power quality problems in electrical systems and can result in increased equipment and conductor heating, misfiring in variable speed drives, and torque pulsations in motors and generators.

The electronic control unit 500, also known as motor control mechanism or electronic control module, is configured to manage the power transfer from the energy source 202 to the electric motor 204 by receiving a variety of inputs signals from different components and determine output control signals such as torque coordination, operation and gearshift strategies, and in some embodiments high-voltage coordination, charging control, on board diagnosis, monitoring, thermal management and the like.

The electronic control unit 500 is electrically connected to each of the DC-DC power converter and the DC-AC inverter 400 and forms a control circuit therewith.

The electronic control unit 500 is configured to inter alia receive indications from sensors in the energy source 202, the DC-DC power converter 300, the DC-AC inverter 400, the electric motor 204, as well as indications based on feedback from the user 502, the environment 504 and other components in an EV (not illustrated) and to determine respective control signals indicative of a required output power for each of the DC-DC power converter 300 and the DC-AC inverter 400.

In one or more embodiments, the electronic control unit 500 is configured to transmit control signals indicative of the required output power to each of the DC-DC power converter 300 and the DC-AC inverter 400 according to inter alia the torque requirements and power requirements of the electric motor 204, as well as indications of measured electrical signals from the DC-DC power converter 300 and the DC-AC inverter 400.

The electronic control unit 500 is configured to balance the reference voltages of the DC-DC power converter 300 and the DC-AC inverter 400 to optimize the efficiency of the dynamic drive train 200. In some embodiments, the electronic control unit 500 may also take into account the health of the energy source 202, the DC-DC power converter 300 and the DC-AC inverter 400 as well as external factors such as the user 502 and/or the environment 504.

The electronic control unit 500 comprises a combination of hardware and software components and acts as a management and in some embodiments as a prediction system for optimizing the operation of the dynamic drive train 200. As a non-limiting example, the electronic control unit 500 may comprise micro-controllers, micro-processors, random-access memory (RAM), flash memory, and a variety of input and output ports and interfaces to interact with EV subsystems and subcomponents.

The electronic control unit 500 may include or be connected to electric machine control system (EMCS), stability control system (SCS), battery management system (BMS), driver mode system (DMS), and vehicle control system (VCS).

In one or more embodiments, the electronic control unit 500 executes one or more artificial intelligence (AI) algorithms to optimize the efficiency of the dynamic drive train 200, while also taking into account the health of the energy source 202, the DC-DC power converter 300 and the DC-AC inverter 400 as well as external factors such as the user 502 and/or the environment 504. Thus, in one or more embodiments, the electronic control unit 500 enables increasing the amount of optimal operating points, reduces the losses in every component, and improves the overall efficiency of the power train system 150.

In one or more embodiments, the electronic control unit 500 receives information from the user 502 and the environment 504 to analyze and manage the power to be converted into motor force, based on a usage profile. The electronic control unit 500 will not be described in more detail herein.

In one or more embodiments, the dynamic drive train 200 may be implemented on a single printed circuit board (PCB). In one or more other embodiments, the dynamic drive train 200 may be implemented on two PCBs, where the DC-DC power converter 300 may be implemented on a first PCB and the DC-AC inverter 400 may be implemented on a second PCB. In one or more embodiments, the electronic control unit 500 may be implemented on a single PCB with the dynamic drive train 200, integrated into one of the first PCB and second PCB or may be implemented on a separate PCB.

It will be appreciated by those skilled in the art that the dynamic drive train 200 may be implemented in different manners without departing from the scope of the present technology.

### DC-DC Power Converter

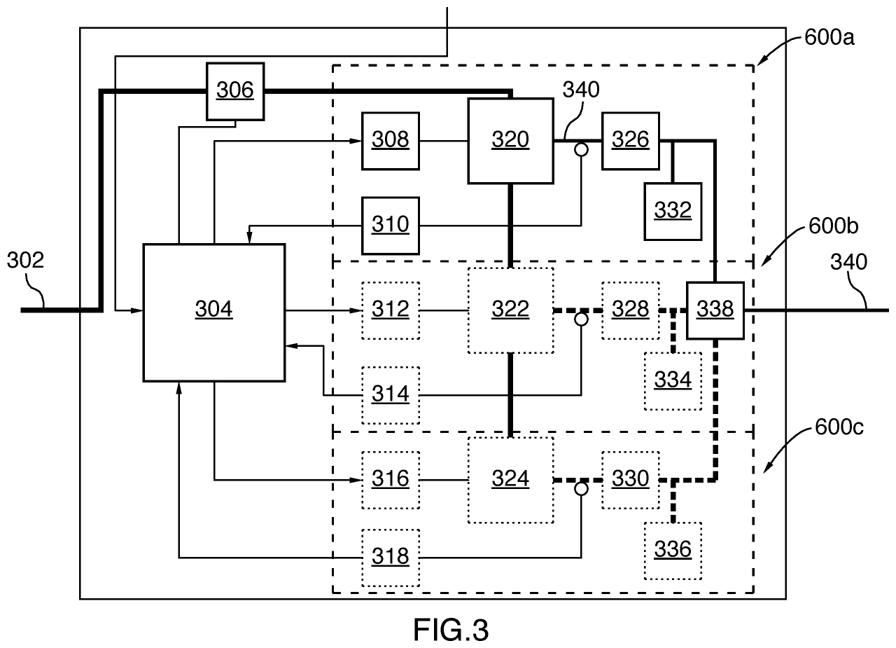

Referring now also to FIG. 3, the DC-DC power converter 300 will now be described in more detail in accordance with one or more non-limiting embodiments of the present technology.

In the context of the present technology, the DC-DC power converter 300 is used for adapting the optimal functioning point of efficiency of the DC-AC inverter 400. The DC-DC power converter 300 acts as an energy converter and to some extent as an energy buffer controller if it is used in an electric source hybrid condition.

The DC-DC power converter 300 comprises inter alia a source DC bus 302, a DC-DC controller 304, a first power sensor 306, at least one single arm switching power converter 600a, 600b, and 600c, a second DC bus 340, and a second power sensor 338.

Each single arm switching power converter 600a, 600b, 600c comprises a respective driver 308, 312, 316, a respective third power sensor 310, 314, 318, a respective half-bridge 320, 322, 324, a respective inductor 326, 328, 330 and a respective capacitor 332, 334, 336.

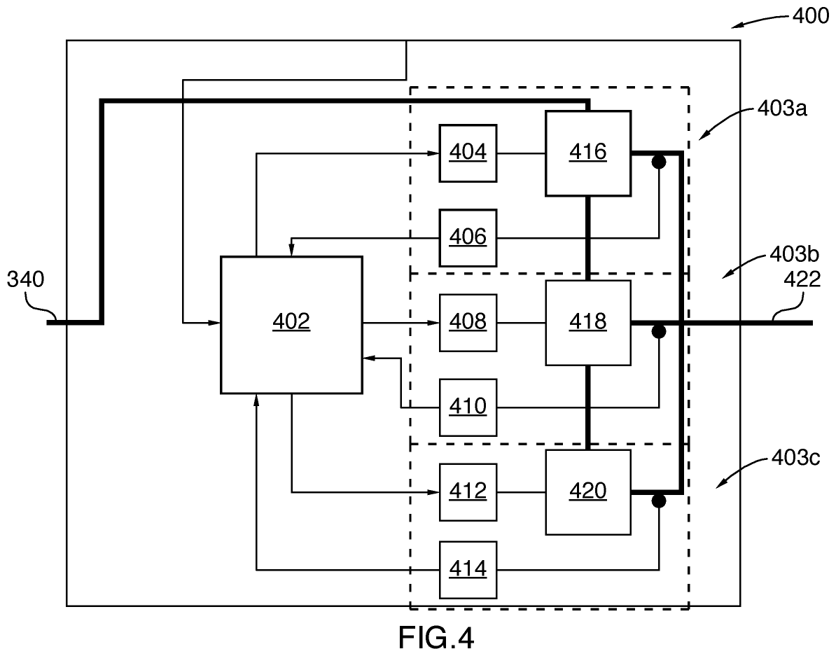

The source DC bus 302 is electrically connected to the first power sensor 306 and to the half-bridge 320, 322, 324 located within the respective single arm switching power converter 600a, 600b, 600c. The half-bridge 320, 322, 324, the respective inductor 326, 328, 330 and the a respective capacitor 332, 334, 336 are electrically connected to the second DC bus 340. The second DC bus 340 is electrically connected to the DC-AC inverter 400 (best seen in FIG. 4).

It will be appreciated the source DC bus 302 and the second DC bus 340 are electrical conductors configured to transfer DC electrical power from the energy source 202 to components across the DC-DC power converter 300 and to the DC-AC inverter 400.

The DC-DC controller 304, the first power sensor 306, the respective driver 308, 312, 316, the respective third power sensor 310, 314, 318 and the second power sensor 338 are electrically connected together to form a control loop or gate loop for inter alia monitoring the electrical power and for controlling the components of the DC-DC power converter 300.

The DC-DC power converter 300 receives the DC signal from the energy source 202 via the source DC bus 302. The first power sensor 306 is electrically connected to the source DC bus 302, and is configured to measure the electrical power flowing through the source DC bus 302 and transmit the measurements (i.e., indication of the DC input signal) to the DC-DC controller 304. It will be appreciated that the first power sensor 306 measures the electrical power flowing through the source DC bus 302 while minimally affecting it. For current sensing, the first power sensor 306 may comprise a hall effect sensor. For voltage sensing, the first power sensor 306 may comprise a divider bridge. In one or more embodiments, the first power sensor 306 may sense a representative value from 0 to 3.3 V of the input DC signal.

The single arm power converter 600a, 600b, 600c is configured to generate the switched DC signal by using the respective half-bridge 320, 322, 324, where the switched DC signal is measured by the respective third power sensor 310, 314, 318, and where the current and voltage waveforms of the switched DC signal is smoothed by the respective inductor 326, 328, 330 and the respective capacitor 332, 334, 336 to obtain the converted DC signal. The driver 308, 312, 316 drives or controls the respective half-bridge 320, 322, 324 to generate the switched DC signal based on control signals received from the DC-DC controller 304.

The DC-DC controller 304 is configured to receive control signals indicative of a required output power of the DC-DC power converter 300. In one or more embodiments, the required output power of the DC-DC power converter 300 corresponds to the required power input of the DC-AC inverter 400.

In one or more embodiments, the control signals indicative of the required output power of the DC-DC power converter 300 may have been determined based on one or more of the input DC signal, the switched DC signal, the output DC signal, the output AC signal, the speed and/or torque requirements of the motor 204, parameters of the energy source 202, temperature of the components, fault detection in the system, and the like.

The DC-DC controller 304 is configured to generate, based on the control signal indicative of the required output power, a pulse-width modulated (PWM) signal to control the respective drivers 308, 312, 316 such that a DC signal with the required power is generated at the output of second DC bus 340 of the DC-DC converter 300.

In one or more embodiments, the DC-DC controller 304 is electrically connected to the electronic control unit 500 to receive and transmit indications and control signals. Additionally or alternatively, the DC-DC controller 304 may be electrically connected to the DC-AC inverter 400 to receive the indications and control signals.

In one or more embodiments, the DC-DC controller 304 is configured to determine the PWM signal based on at least the indication of the input DC signal and the indication of the required power input of the DC-AC inverter 400.

In some embodiments, the DC-DC controller 304 is further configured to receive at least one of an indication of the measured input DC signal from the first power sensor 306 and an indication of the measured output switched DC signal from the third power sensor 310, 314, 318 and to generate, further based on the at least one indication of the received measured input DC signal and the indication of the measured output switched DC signal, a pulse-width modulated (PWM) signal, which is then transmitted to the driver 308, 312, 316.

Each driver 308, 312, 316 is configured to receive the PWM signal from the DC-DC controller 304 and generate and transmit, based on the PWM signal, a control signal for selectively activating a high side and low side transistor gate of the respective half-bridges 320, 322, 324 to output switched DC signal.

The half-bridge 320, 322, 324 is configured to generate, by receiving the input DC signal and based on the control signal provided by the respective driver 308, 312, 316, a switched DC signal. The switched DC signal output from the half-bridge 320, 322, 324 is thereafter transmitted to respective inductor 326, 328, 330 and to a ground (not illustrated).

It will be appreciated that the half-bridge 320, 322, 324 serves as a mean to vary the voltage of the input DC signal to generate a switched DC signal by charging and discharging the inductors 326, 328, 330 (or motor coil if it is the load) at high frequencies. The switched DC signal output from the half-bridge 320, 322, 324 is transmitted to a respective inductor 326, 328, 330. The inductor 326, 328, 330 is configured to smooth the current waveform in the switched DC signal and store the electrical energy as magnetic energy.

The smoothed switched DC signal output by the inductor 326, 328, 330 is transmitted to a respective capacitor 332, 334, 336 and then to the DC bus 340. In one or more embodiments, the capacitor 332, 334, 336 is configured to smooth the voltage waveform of the switched DC signal by storing the electrical energy in an electric field to obtain the output DC signal, which is then transmitted to the DC bus 340. While there is only one respective capacitor 332, 334, 336 it should be understood that there may be a plurality of capacitors in each half-bridge 320, 322, 324.

In some embodiments, the switched DC signal transmitted by each of the half-bridge 320, 322, 324 to the respective inductor 326, 328, 330 is measured by a respective third power sensor 310, 314, 318 and an indication of the resulting measurement is transmitted to the DC-DC controller 304. Each third power sensor 310, 314, 318 is configured to measure a state of saturation of the respective inductor 326, 328, 330 to provide feedback to the control loop comprising the DC-DC controller 304. The DC-DC controller 304 may vary the PWM signal provided to the drivers 308, 312, 316 according to the indication received from the third power sensor 310, 314, 318.

The DC bus 340 transmits the converted or output DC signal from the DC-DC power converter 300 to the DC-AC inverter 400.

In one or more embodiments, the converted DC signal output from the DC-DC power converter 300 is measured by the second power sensor 338. The second power sensor 338 is connected to the DC bus 340 between the DC-DC power converter 300 and the DC-AC controller 402. In some embodiments, the second power sensor 338 is configured to transmit an indication of the measured converted DC signal to at least one of the DC-DC controller 304, the DC-AC controller 402 and the electronic control unit 500 as feedback for the control loop. In one or more embodiments, the second power sensor 338 is configured sense a representative value from 0 to 3.3 V of the input DC signal.

It should be understood that the number of single arm switching power converters 600a, 600b, 600c may vary from embodiment to embodiment and depending on the application, and the number of single arm switching power converters 600a, 600b, 600c illustrated in FIG. 3 is exemplary only.

In one or more other embodiments, the number of half-bridges 320, 322, and 324 may vary depending on the application.

In one or more alternative embodiments of the present technology, the number of half-bridge 320, 322, 324 may be doubled at each location so as to form full bridges (i.e., each half-bridge 320, 322, 324 is replaced by a full bridge comprising two half-bridges). It will be appreciated that in such instances, the electrical connections and components within the respective single arm switching power converters 600a, 600b, 600c may be positioned differently. It will be further appreciated that the full bridges may be interleaved.

In one or more embodiments, the DC-DC power converter 300 is implemented as a bidirectional full bridge buck boost DC-DC power converter based on Gallium Nitride (GaN) transistors. In the context of the present technology, GaN transistors are used in the single arm switching power converters 600a, 600b, 600c of the DC-DC power converter 300 to switch power quickly while maintaining a very high frequency of operation. Due to their low “on resistance” substrate and their high band gap, it will be appreciated that GaN transistors can reach higher frequencies more efficiently.

In one or more embodiments, the DC-DC power converter 300 is configured to operate at a lower power range, such as between 250 W to 5 KW in combination with the

DC-AC inverter 400 operating at the same power range. It will be appreciated that the present technology is not limited to GaN transistors, and different types of transistors may be used as long as such transistors can operate at very high frequencies. For instance, in one or more alternative embodiment, the transistors may include one or more of: bipolar junction transistors (BJTs), field-effect transistors (FETs), metal-oxide-semiconductor field-effect transistors (MOSFETs), insulated gate bipolar transistors (IGBTs) and the like.

In one or more embodiments, a given driver 308, 312, 316 may be implemented as a LMG1210 available from Texas Instruments (TI) (Texas Instruments Incorporated, Dallas, Texas, U.S.), which is a 200-V half-bridge MOSFET and Gallium Nitride Field Effect Transistor (GaN FET) operating at frequencies up to 50 MHz, which does not have a perfect waveform signal but enables driving high frequencies, which is suitable for high frequency power conversion applications and enables reducing the size of the components of the dynamic drive train 200.

### DC-AC Inverter

With reference to FIG. 4, the DC-AC inverter 400 will now be described in more detail in accordance with one or more non-limiting embodiments of the present technology.

In the context of the present technology, the DC-AC inverter 400 is not used to increase frequency of the signal as it has negligible effects on the efficiency and/or formfactor of the motor 106. Developers of the present technology have appreciated that having the cleanest possible output waveform, defined by a near perfect square wave that has the sharpest edge and that contains the least harmonics possible, enables minimizing residual signals generated by switching, which can be considered as wasted energy as well as hazardous for the motor 204 itself.

Overshoots and sharp transients in the motor are known to be destructive to the motor in extensive usage, due to overshoots in voltages breaking the dielectric barrier over time. In the long term, the dielectric barrier fragilize itself proportionally to the amount of overshoots it takes. After the dielectric barrier fails, a short circuit between the rest of the winding is created, shorting the whole motor, and damaging it. The reduction of transients also comes with a much more precise control, and better efficiency, as transients are losses of energy which do not provide wanted torque on the mechanical shaft. Thus, by generating cleaner waveforms, the DC-AC inverter 400 enables improving the performance and longevity of the motor 204.

The DC-AC inverter 400 comprises the DC bus 340, a single arm switching power inverter 403a, 403b 403c, a DC-AC controller 402, and a motor bus 422.

The respective second single arm switching power inverter 403a, 403b, 403c is similar to the respective single arm switching power converter 600a, 600b, 600c, but without the capacitor 332, 334, 336 and the inductor 326, 328, 330. Each second single arm switching power inverter 403a, 403b, 403c comprises a respective second driver 404, 408, 412, a respective second half-bridge 416, 418, 420 and a respective fourth power sensor 406, 410, 414.

The respective second single arm switching power inverter 403a, 403b, 403c is configured to generate the output AC signal via the second half-bridge 416, 418, 420 by converting the output DC signal. The output AC signal is measured by the respective fourth power sensor 406, 410, 414.

The DC bus 340, the second half-bridge 416, 418, 420 and the motor bus 422 form a power loop for transmission of electrical power from the DC-DC power converter 400 to the motor 204.

The DC-AC controller 402, the respective second driver 404, 408, 412 and the respective fourth power sensor 406, 410, 414 form a control loop. It will be appreciated that that the DC-AC controller 402 is also electrically connected to the DC-DC controller 304, the second power sensor 338, and the electronic control unit 500 to form the control loop.

The respective second driver 404, 408, 412 control or drive the respective second half-bridge 416, 418, 420 to generate the output AC signal by converting the output DC signal based on control signals received from the DC-AC controller 402.

The DC-AC controller 402 is configured to receive signals comprising indications of a required output of the DC-AC inverter 400. In one or more embodiments, the indication of the required inverter output comprises a required torque and required speed for driving the motor 204.

In one or more embodiments, the signals indicative of the required output of the DC-AC inverter 400 may be determined based on one or more of the input DC signal, the switched DC signal, the output DC signal, the output AC signal, the speed and/or torque requirements of the motor 204, temperature of the components, fault detection in the system and the like.

In one or more embodiments, the DC-AC controller 402 receives the signal indicative of the required inverter output from the electronic control unit 500. In one or more other embodiments, the DC-AC controller 402 may determine the required output based on information received from at least the motor 204.

The DC-AC controller 402 is configured to generate, based on the indication of the output DC signal and the signal indicative of the required inverter output, a pulse-width modulated (PWM) signal to control the respective drivers 404, 408, 412 such that an AC signal with the required parameters is generated at the output of motor bus 422 and transmitted to the electric motor 204.

In one or more embodiments, the DC-AC controller 402 is configured to receive an indication of a reference speed and a reference torque for the motor 204 from the electronic control unit 500, and to receive an indication of the measured converted DC signal based on the converted DC signal received from the DC-DC power converter 300.

The DC-AC controller 402 is configured to: determine, based on the signal indicative of the required inverter output comprising at least one of the reference speed and the reference torque and the indication of the converted DC signal, the second PWM signal indicative of the converted AC signal. The DC-AC controller 402 is configured to transmit the second PWM signal to the second drivers 404, 408, 412, which cause the second half-bridge 416, 418, 420 to generate and output the converted AC signal using the output DC signal.

In one or more embodiments, the second driver 404, 408,412 is configured to operate at high voltages, which improves the overall system efficiency, as each of the second half-bridges 416, 418, 420 requires high voltages to open and close its gates. Thus, by using the second driver 404, 408, 412 designed and configured for high voltage uses, the 100V GaN transistors can be charged and discharged more rapidly than standard drivers would, thus allowing sharper rise and fall time of the transistors and providing sharper waveforms in the output AC signal to the electric motor 204.

In one or more embodiments, the DC-AC controller 402 is further configured to receive an indication of the measured converted AC signal from the fourth power sensors 406, 410, 414, and to generate, based on indication of the measured converted AC signal, the indication of the measured output DC signal and the indication of the required inverter output, a second PWM signal for transmission to the second driver 404, 408, 412. Each second driver 404, 408, 412 is configured to receive the second PWM signal from the DC-AC controller 402, and to transmit, based on the second PWM signal, a second control signal to the second half-bridge 416, 418, 420. The second half-bridge 416, 418, 420 is configured to receive the converted DC signal from the second bus 340, receive the second control signal from the second drivers 404, 408, 412, and to convert the output DC signal into a converted AC signal based on the second control signal.

The second half-bridges 416, 418, 420 are configured to convert the DC signal into a converted AC signal, and transmit the converted AC signal to the motor 204 via the motor bus 422 electrically connected to the motor 204. It will be appreciated that the AC signal output by the second half-bridges 416, 418, 420 is measured by the fourth power sensors 406, 410, 414 respectively, which provide the measurements to at least the DC-AC controller 402 as feedback in the control loop.

In one or more embodiments, the fourth power sensor 406, 410, 414 is in the form of hall effect sensor that sense the variation of the phase current that is fed to the motor bus 422. In other embodiments, the fourth power sensor 406, 410, 414 is a shunt sensors which sense the back electromotive force (Back-EMF). In this configuration, the shunt sensors measure the phase that is not powered by the DC-AC inverter 400, such as only two phases out of three that are powered by cycle.

In one or more embodiments, a given second driver 404, 408, 412 may be implemented as NCP51820 available from Onsemi (ON Semiconductor Corporation, Phoenix, Arizona, US), which is a 650 V half bridge gate driver for GaN power switches, which has a lower frequency operating range and which is conventionally used for 650V GaN transistors (instead of 100 V GaN transistors as in the present case) but which enables generating a waveform of higher quality compared to a given driver 308, 312, 316 of the DC-DC power converter 300. The DC-AC inverter 400 operates at the same power range as the DC-DC power converter 300.

In some embodiments, the DC-AC inverter 400 is operable to generate an AC signal with a frequency which may be between 500 kHz to 100 MHz. In other embodiments, the frequency of the output AC signal may be comprised between 500 kHz to 10 MHz.

It should be noted that in one or more alternative embodiments of the present technology, the DC-AC inverter 400 may operate in the same frequency range as the DC-DC power converter 300, such as with coreless electric motors for example.

### Single Arm Switching Power Converter

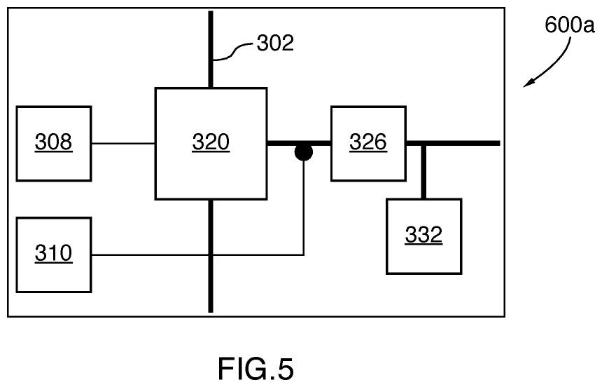

Referring also to FIG. 5, the single arm switching power converter 600a which may be one of the single arm switching power converter 600a, 600b, 600c included in the DC-DC power converter 300 will now be described in more detail in accordance with one or more non-limiting embodiments of the present technology.

The single arm switching power converter 600 is also known as a core cell or a commutation system.

The single arm switching power converter 600 comprises inter alia the driver 308, the third power sensor 310, a half-bridge 320, an inductor 326, and a capacitor 332.

The driver 602 is electrically connected to the half-bridge 320, the half-bridge 320 being electrically connected to the source DC bus 302 and to the inductor 326.

The half-bridge 320 is configured to receive the DC signal from the source DC bus 302 and to transmit a switched DC signal to the inductor 326. The inductor 326 is connected in parallel with the capacitor 332 and to the DC bus 340 and is configured to output a smoothed switched DC signal. The switched DC signal provided to the inductor 326 from the half-bridge 320 is measured by the third power sensor 310, and the measurement is transmitted to the DC-DC controller 304. It will thus be understood that the foregoing embodiment of the single arm switching power converter 600a is included in the DC-DC power converter 300 and can be connected in parallel with at least one other of the single arm switching power converter (e.g., 600b, 600c) to stabilize the output DC signal.

In one or more embodiments, the inductor 326 is configured to receive the switched DC signal and to generate a smoothed switched DC signal, and the capacitor 332 is configured to receive the smoothed switched DC signal and to generate the converted DC signal. In one or more embodiments, the inductor 326 is connected in parallel with the capacitor 332.

In some embodiments, combining multiple single arm switching power converters such as single arm switching power converters 600a, 600b, 600c enable improving the system characteristics. For instance, connecting a plurality of single arm switching power converters 600a, 600b, and 600c in series enables outputting greater output voltages than conventional drive trains. Additionally, interleaving a plurality of single arm switching power converters 600a, 600b, and 600c connected in parallel enables outputting a wider power range than in conventional drive trains, thus ensuring stability and efficiency in the delivered electrical power to the electric motor 204, depending on the requirements in speed and torque. Having a plurality of interleaved single arm switching power converters 600a, 600b, and 600c connected in parallel also enables having a better control of the output electrical power, thus reducing the required filtering of the output DC signal, and enables maintaining a functional system in the case where one of the single arm switching power converters 600a, 600b, and 600c stops functioning.

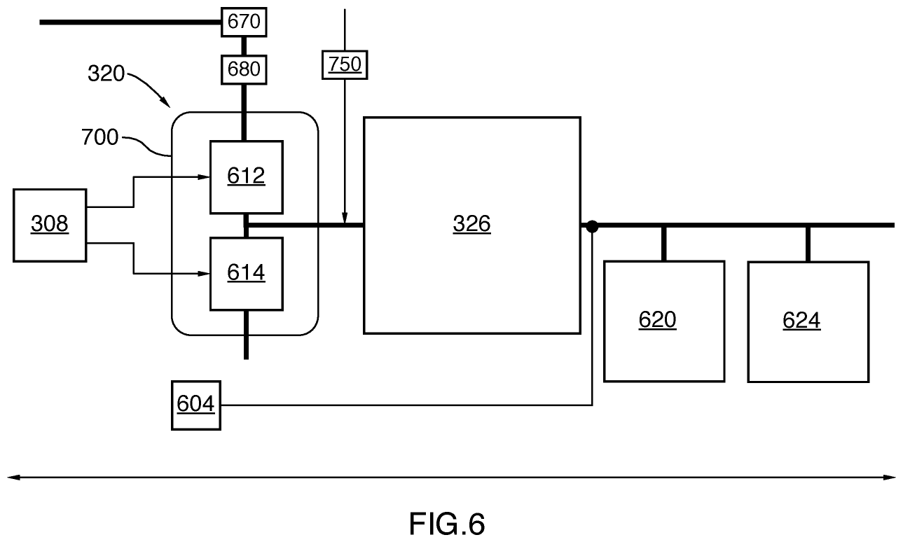

With reference to FIG. 6, components of the half-bridge 606 are illustrated in accordance with one or more non-limiting embodiments of the present technology.

The half-bridge 606 may replace one or more of the half bridges 320, 322, 324 of the DC-DC power converter 300.

The half-bridge 606 comprises inter alia a first set of capacitors 670, a second set of capacitors 680, a high side transistor 612 and a low side transistor 614 and a cooling system 700.

The high side transistor 612 and the low side transistor 614 are both in thermal contact with a thermal heatsink in the cooling system 700, which serves as a thermal regulator for the transistors 612, 614.

The half-bridge 320 comprises the first set of capacitors 670 and the second set of capacitors 680, which are configured to smooth the transients in the DC signal, as will be explained below. Further, it will be appreciated that in the foregoing embodiment, two capacitors 620, 624 are connected to the DC bus 601 to improve smoothing of the switched DC signal and to increase the amount of electrical energy stored in the electric field.

In one or more embodiments, the half-bridge 606 may be replaced by a full-bridge (i.e., two half-bridges) to enable buck and boost switching.

The high side transistor 612 is electrically connected to the high side of the source DC bus 302 and to the inductor 326. The high side transistor 612 is configured to receive the input DC signal from the source DC bus 302 to generate a switched DC signal to the inductor 326 when activated by the driver 308. The high side transistor 612 is configured to transmit the switched DC signal to the inductor 326 in response to the control signal from the driver 308. The high side transistor 612 is thus configured to charge the inductor 326 or the motor coil.

The low side transistor 614 is connected to a ground (not illustrated) and to the inductor 608. The low side transistor 614 is configured is configured to receive the input DC signal from the source DC bus 302 and to stop providing the switched DC signal to the inductor 608 when activated by the driver 308. The low side transistor 614 is configured to stop transmission of the switched DC signal to the inductor 608 in response to the control signal received from the driver 308. The low side transistor 614 is thus configured to discharge the inductor 326 or the motor coil.

During operation of the half-bridge 320, only one of the high side transistor 612 and the low side transistor 614 is activated at a time to avoid damaging the system by shorting the provided DC signal to the ground.

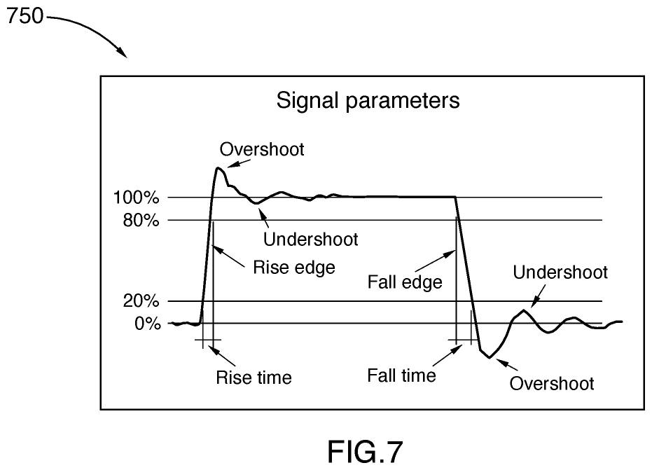

Referring also to FIG. 7, there is illustrated a graph 750 showing a typical signal resulting from subsequent activations of the high side transistor 612 and the low side transistor 614, the signal being provided in the form of a voltage (y-axis) as a function of time (x-axis). When the high side transistor 612 is activated, it takes a certain amount of time, referred to as rise time, to reach a first predefined percentage of the target value, e.g., 80% of the targeted value. In some embodiments, due to system imperfections, the voltage may overshoot and undershoot the target of 100% before stabilizing over time, which may cause damages to the system and lower the overall efficiency. Similarly, when the low side transistor 614 is activated, it takes a certain amount of time, referred to as fall time, to reach a second predefined percentage of the target value, e.g., 20% of the targeted value. In some embodiments, due to system imperfections, the voltage may overshoot and/or undershoot the target of 0% before stabilizing over time, which may lower the overall efficiency. It will be understood that the aforementioned characteristic parameters of the signal may be influenced by system components, such as the circuitry, the transistor, the capacitors, the inductors, and the like.

In some embodiments, the DC-AC inverter 400 also comprises the single arm switching power converter 600, which are connected to the DC-AC controller 402 and convert a DC signal into an AC signal.

In one or more embodiments, a multi-phase signal can be generated and transmitted to the motor 204 by using more than one single arm switching power inverter (e.g., second single arm switching power inverter 403a, 403b, 403c of FIG. 4) in the DC-AC inverter 400.

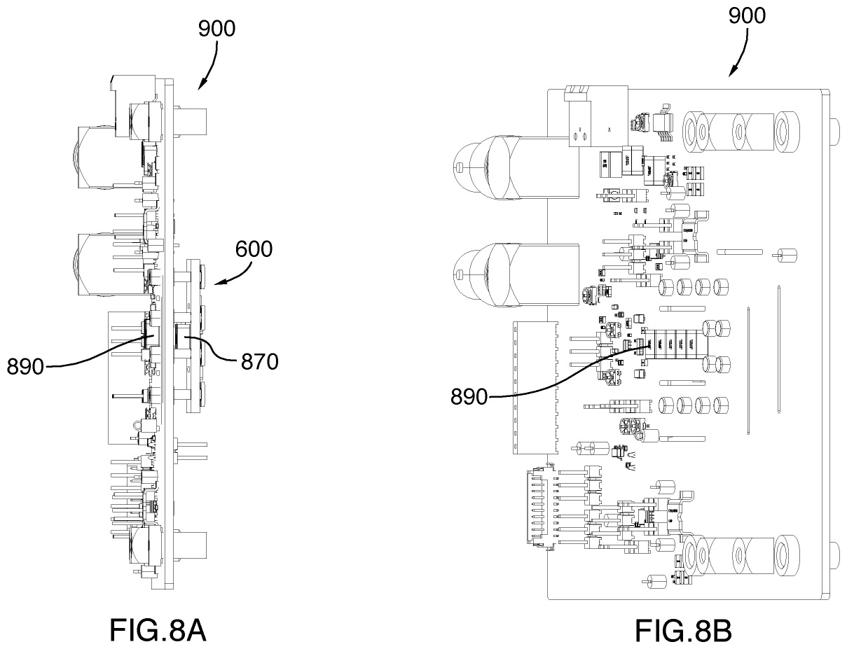

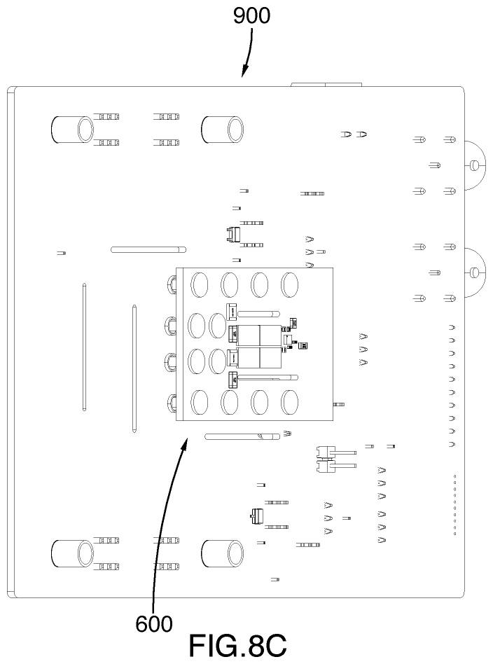

FIGS. 8 to 11 illustrate various components of the DC-DC power converter implemented on printed circuit boards (PCBs).

FIGS. 8A, 8B and 8C illustrate respectively a side view, a bottom perspective view and a top perspective view of a half-bridge and a single arm switching power converter of a DC-DC power converter implemented on a PCB in accordance with one or more non-limiting embodiments of the present technology.

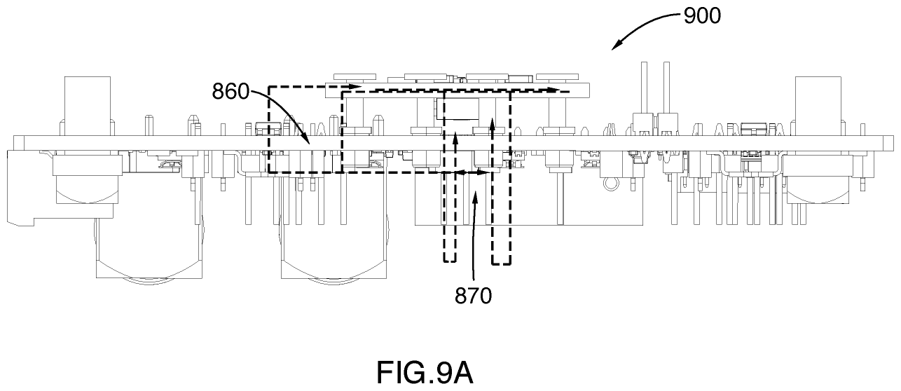

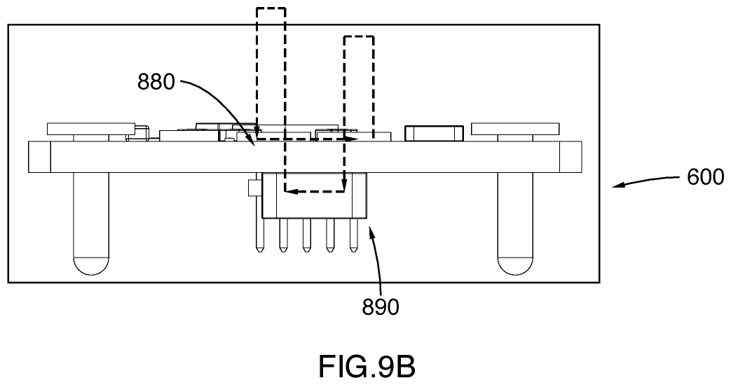

FIGS. 9A and 9B illustrate respectively a bottom view and a top view of the DC-DC power converter with the single arm switching power converter removed in accordance with one or more non-limiting embodiments of the present technology.

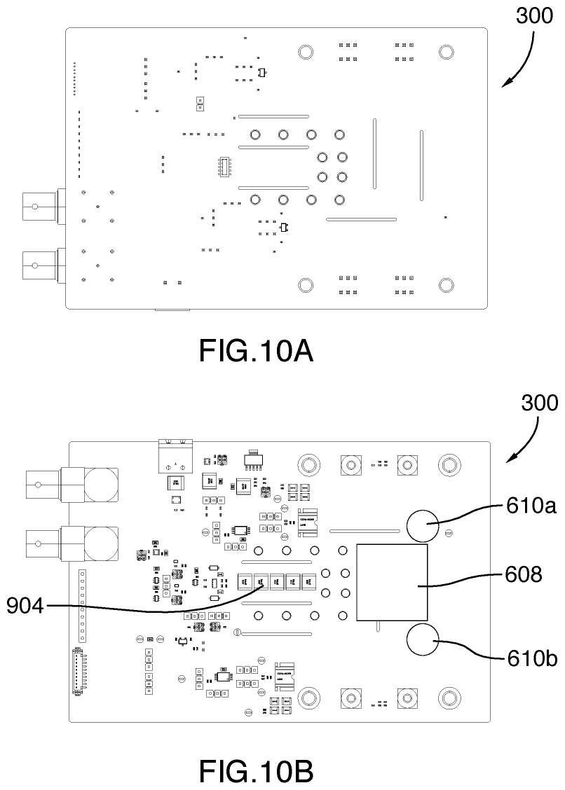

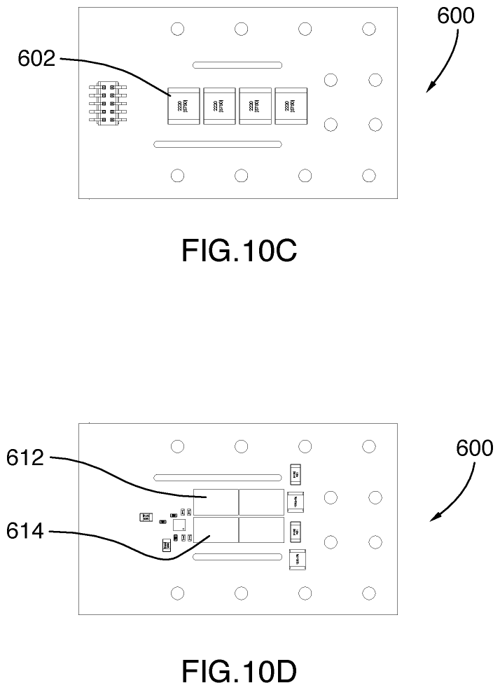

FIGS. 10A, 10B, 10C and 10D illustrate respectively a bottom view and a top view of the DC-DC power converter 300 with the single arm switching power converter 600 removed, and a bottom view and a top view of the single arm switching power converter 600 removed from the DC-DC power converter 300 in accordance with one or more non-limiting embodiments of the present technology.

### Power Loops

FIGS. 9A and 9B illustrate a gate loop 802 and a power loop 804 on a dynamic drive train in accordance with one or more non-limiting embodiments of the present technology.

It will be appreciated that electrical power loops are critical in the overall performance of a dynamic drive train such as the dynamic drive train 200. Having longer electrical power loops typically results in more parasitic elements in the signal and drastically amplifies the noise created when the switching occurs in the transistors. Every millimeter of trace added in the electrical loops may cause more overshoots and undershoots in the signal which may damage the transistors and reduce the overall efficiency of the dynamic drive train 200.

Capacitors of various sizes may be used to filter parasitic noise on various frequencies. Typically, capacitors with high capacitance tend to have a larger form-factor, thus being more difficult to fit next to the single arm switching power converters. The use of such large form-factor capacitors may be omitted to reduce the lengths of loops, at a cost of not filtering the noise of low frequencies, which limits the amount of usable power.

Further, thermal cooling is often prioritized and thermal cooling components are placed next to the single arm switching power converters, which increases the length of the loops. Typically, heatsinks are fixed on one of the lateral surfaces of the transistors using thermal paste. It should be understood that the transistors must be maintained below a critical temperature to avoid being damaged or destroyed.

The gate loop 802 comprises a circuitry that connects the drivers 308, 312, 316, second drivers 404, 408, 412, the DC-DC controller 304, the DC-AC controller 402 and the single arm switching power converters 600a, 600b, 600c, the second single arm switching power inverter 403a, 403b, 403c and provides electrical current for activating the transistors in the half-bridges 320, 322, 324, and the second half-bridges 416, 418, 420.

The power loop 804 comprises electrical circuitry that connects the energy source 202, the DC-DC power converter 300, the DC-AC inverter 400 and the motor 106. In one or more embodiments, the electrical circuitry comprises a source DC bus, a second DC bus and a motor AC bus. It should be understood that the current circulating in the power loop 804 is usually greater than the current circulating in the gate loop 802.

Still referring to FIGS. 9A and 9B, the gate loop 802 overlaps with the power loop 804. It will be appreciated that overlapping the loops 802, 804 requires the use of top cooled transistors, which may be less efficient in extracting heat than bottom cooled transistors. However, in the context of the present technology, due to the circuit layout, top cooled transistors are used and enable minimizing the length of the loops 802, 804, which is beneficial for operation of the dynamic drive train 200.

Further, overlapping the loops 802, 804 enables using multiple ranges of filtering capacitors and bulkier capacitors compared to the dispositions known in the art, thereby allowing the dynamic drive train 200 to operate at high frequencies and at high powers.

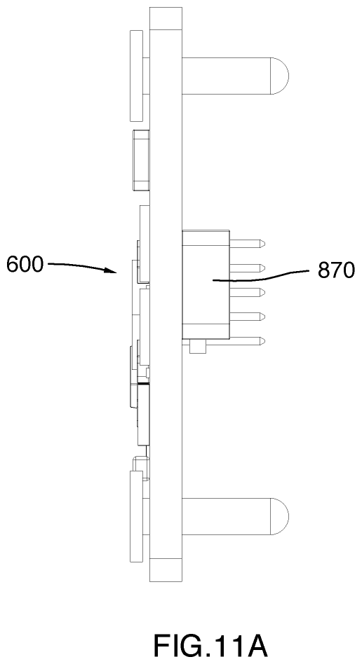

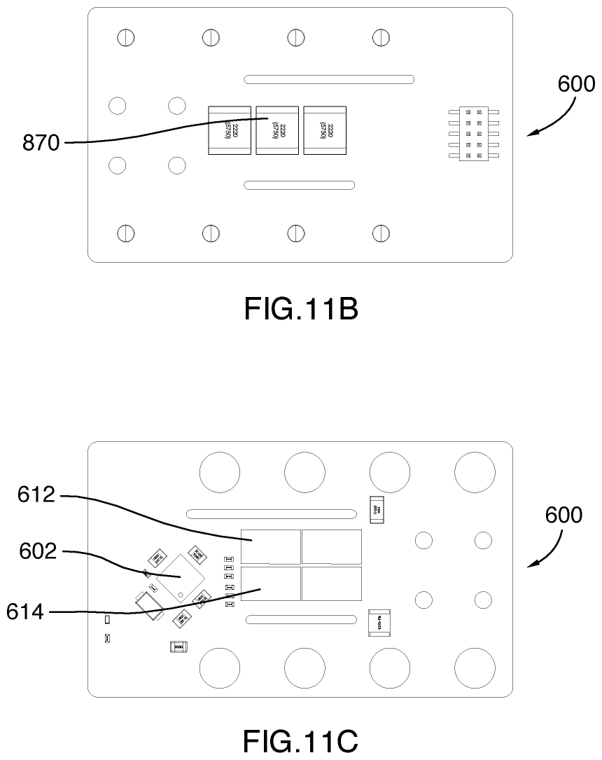

The power loop 804 comprises a main decoupling loop 860 and a support loop 880. The main decoupling loop 860 comprises the first set of capacitors 870 (also seen in FIG. 8A, and FIGS. 11A to 11B) which corresponds to the first set of capacitors 670 (FIG. 5) and the support loop 880 comprises the second set of capacitors 890 (also seen in FIG. FIG. 8A), which correspond to the second set of capacitors 680 (FIG. 5).

The main decoupling loop 860 provides straight to the transistors (e.g., GaNs) in the half-bridges (not numbered) in the single arm switching power converter 600, the charges required at instant t=0+, meaning that when the transistors close, the charges are transmitted from the first set of capacitors 870 to smoothen the transients. These are the lowest resistance paths possible, as the capacitors 870 themselves are very low equivalent series resistance (ESR)/equivalent series inductance (ESL) (e.g., MultiLayer Ceramic Capacitors (MLCC)). Because of these characteristics, the set of capacitors 870 have a low capacity to store energy, and due to the high power going through the circuit, the first set of capacitors 870 may not be as useful in their action when discharged. A second decoupling loop 880 or support loop 880 is present to counteract the effect of the first set of capacitors 870 in the main decoupling loop 860. Further away from the design, but still very close in comparison to DC bus capacitors with larger form factors, the second set of capacitors 890 in the support loop 880 acts as a secondary reservoir to support the main decoupling loop 860, and still provides enough charges to the main decoupling loop 860 as well as providing direct charges passing through the closed transistors. Using this configuration comprising the main decoupling loop 860 and the support loop 880, the present technology can reach the full harmonic spectrum of the transients to provide an optimal waveform.

### Thermal Solution

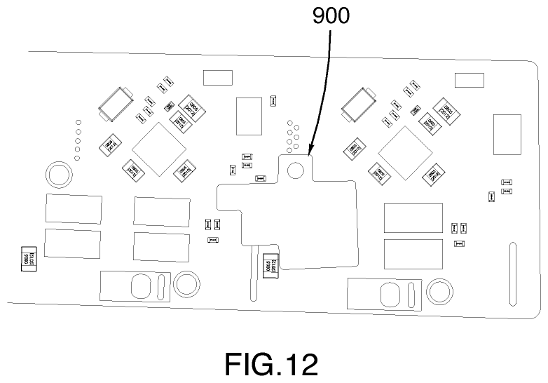

FIG. 12 illustrates a perspective view of a heat spreader fixed on the half-bridge of FIG. 6 in accordance with one or more non-limiting embodiments of the present technology.

The heat spreader 900 part of the cooling system 700 (FIG. 7) is configured to transfer heat generated by the electronic components in the half-bridge where it is dissipated away from the electronic components to enable regulation of temperature and ensure optimal functioning of the components.

High voltage transistors such as GaN transistors typically generate high amounts of heat concentrated in small areas, and it is usually difficult to extract heat due to a fuzzy bonding between the transistors and the heatsink. Using the heat spreader 900 enables to efficiently extract heat from high voltage transistors and to avoid damages caused by high temperatures.

The heat spreader 900 is fixed, using a thermal paste, onto the top surface of the transistors (e.g. high side transistor 612 and low side transistor 614). The heat spreader 900 is in contact with the high side transistor 612 and the low side transistor 614 (seen in FIG. 6). In some embodiments, the thermal solution further comprises a heatsink (not illustrated), which is typically fixed on the heat spreader 900 using thermal paste. The heatsink typically consists of a plate having a plurality of parallel fins extending from its surface.

When the transistors operate, heat is generated, the heat spreader will conduct the generated heat in ambient air, thereby maintaining the transistors at an operable temperature range. In some embodiments, the operable temperature range is between 70° C. to 90° C. In one embodiment, the maximum working temperature of the transistors is 135° C. In some embodiments, the heatsink and the heat spreader 900 are at least composed of one of aluminium and of copper. It will be appreciated that the heatsink and heat spreader may include composite materials.

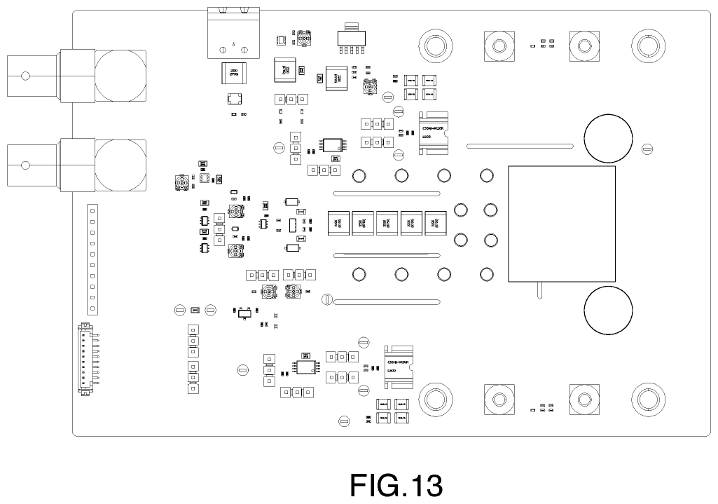

FIG. 13 illustrates a top view of a power converter in accordance with one or more non-limiting embodiments of the present technology.

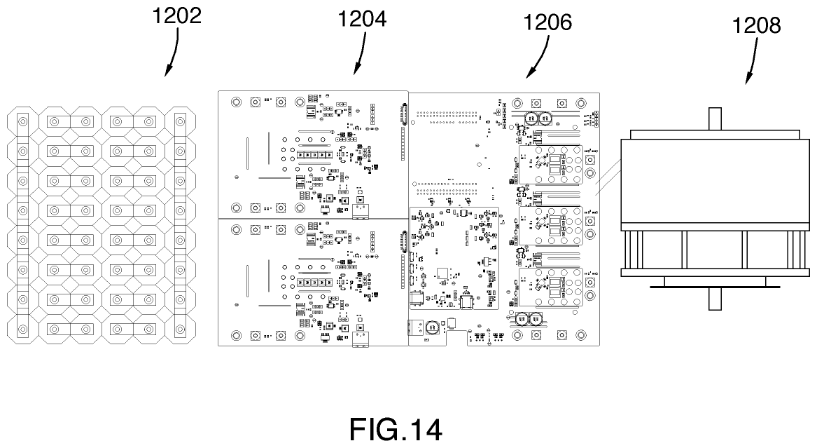

FIG. 14 illustrates a top view of a dynamic drive train 1200 comprising battery cells 1202, a DC-DC power converter 1204, a DC-AC inverter 1206 and a motor 1208 in accordance with one or more non-limiting embodiments of the present technology.

One or more embodiments of the present technology enable adding design flexibility and minimizing compromises in system performances of power train systems in EVs. By placing a high-frequency DC-DC power converter in between an inverter and a battery, one or more embodiments the present technology enable the motor controller/inverter and the motor to be sized apart from one to another. By having as an input a controller configured to change the DC bus proprieties, the high-frequency DC-DC power converter enables generating a wide range of voltages and currents output in order to match the demand of the motor drive. Having a high frequency DC-DC power converter (and corresponding inverter) enables reducing the form factor of an electrical power drive train, as well as having an almost instantaneous response time (i.e., by providing minimal lag or voltage drop between transients). Thus, the battery may be sized according to mechanical constraints, without having to comply with the required power input of the motor, and vice versa. As a result, the DC-DC power converter acts as a sizing buffer.

It should be expressly understood that not all technical effects mentioned herein need to be enjoyed in each and every embodiment of the present technology. For example, embodiments of the present technology may be implemented without the user enjoying some of these technical effects, while other non-limiting embodiments may be implemented with the user enjoying other technical effects or none at all.

Some of these steps and signal sending-receiving are well known in the art and, as such, have been omitted in certain portions of this description for the sake of simplicity. The signals can be sent-received using optical means (such as a fiber-optic connection), electronic means (such as using wired or wireless connection), and mechanical means (such as pressure-based, temperature based or any other suitable physical parameter based).

Modifications and improvements to the above-described implementations of the present technology may become apparent to those skilled in the art. The foregoing description is intended to be exemplary rather than limiting.

What is claimed is:

1. A dynamic drive train for an electric vehicle comprising:
a high frequency direct current (DC)-DC power converter electrically connectable to an energy source to receive an input DC signal therefrom, the high frequency DC-DC power converter comprising:
at least one single arm switching power converter, comprising:
a half-bridge electrically connectable to the energy source, the half-bridge being in thermal contact with a cooling system comprising a heat spreader;
an inductor electrically connected to the half-bridge; and
at least one capacitor electrically connected parallel to the inductor; and
a driver;
a DC-DC controller operatively connected to the driver, wherein the DC-DC controller is configured to:
receive an indication of a required power output;
receive an indication of the input DC signal; and
generate, based on the indication of the input DC signal and the indication of the required power output, a pulse-width modulated (PWM) signal; and
transmit the PWM signal to the driver,
and wherein the driver is configured to:
receive the PWM signal from the DC-DC controller;
generate, based on the PWM signal, a control signal; and
transmit the control signal to the half-bridge, the control signal causing the half-bridge to convert the input DC signal into a switched DC signal transmitted to the inductor and the at least one capacitor to obtain an output DC signal, the output DC signal having the required power output; and
a DC-alternative current (AC) inverter electrically connected to the high frequency DC-DC power converter to receive the output DC signal therefrom, the DC-AC inverter being electrically connectable to an electric motor, the DC-AC inverter being configured to:
receive an indication of a required inverter output; and
convert, based on the indication of the required inverter output and the indication the output DC signal, the output DC signal into an output AC signal.

2. The dynamic drive train of claim 1, wherein the indication of the required inverter output comprise at least one of a required speed and required torque.

3. The dynamic drive train of claim 1 or 2, further comprising:
a first DC bus having an input electrically connectable to the energy source and being electrically connected to the half-bridge;
a second DC bus electrically connected to the inductor and the capacitor and to the DC-AC inverter; and
a AC bus electrically connected to the DC-AC inverter and having an output electrically connectable to the electric motor.

4. The dynamic drive train of claim 3, further comprising a first power sensor electrically connected to the first DC bus and to the at least one single arm switching power converter, the first power sensor being configured to:
measure the input DC signal to obtain the indication of the input DC signal, and
transmit the indication of the input DC signal to the DC-DC controller.

5. The dynamic drive train of claim 4, wherein the half-bridge comprises a first half-bridge, the driver comprises a first driver, the PWM signal comprises a first PWM signal, and the control signal comprises a first control signal, and wherein the DC-AC inverter comprises:
a DC-AC controller configured to:
receive the indication of the required inverter output;
receive an indication of the output DC signal; and
generate, based on the indication of the output DC signal and the indication of the required inverter output, a second PWM signal; and
at least one single arm switching power inverter, comprising:
a second half-bridge electrically connected to the second DC bus and the AC bus; and
a second driver electrically connected to the DC-AC controller, the second driver being configured to:
receive the second PWM signal from the DC-AC controller; and
transmit the second control signal to the second half-bridge, the second control signal causing the second half-bridge to convert the output DC signal into the output AC signal.

6. The dynamic drive train of any one of claims 3 to 5, further comprising a second power sensor electrically connected to the second DC bus and to the AC bus, the second power sensor being configured to:
measure the output DC signal to obtain the indication of the output DC signal, and
transmit the indication of the output DC signal to the DC-AC controller for generating the second PWM signal.

7. The dynamic drive train of any one of claims 3 to 6, further comprising:
a third power sensor electrically connected to the second DC bus between the first half-bridge and the first inductor, the third power sensor being configured to:
measure the switched DC signal to obtain an indication of the output switched DC signal, and
transmit an indication of the output switched DC signal to the DC-DC controller for generating the first PWM signal.

8. The dynamic drive train of any one of claims 3 to 7, further comprising:
a fourth power sensor electrically connected to the AC bus downstream the second half-bridge, the third power sensor being configured to:
measure the output AC signal to obtain an indication of the output AC signal, and
transmit an indication of the output AC signal to the DC-AC controller for generating the second PWM signal.

9. The dynamic drive train of any one of claims 1 to 8, wherein:
the first half-bridge comprises a first high side transistor and a first low side transistor; and wherein
the first driver is configured to selectively activate one of the first high side transistor and the first low side transistor based on the first control signal to obtain the switched DC signal, and

10. The dynamic drive train of any one of claims 5 to 9, wherein:
the second half-bridge comprises a second high side transistor and a second low side transistor, and wherein
the second driver is configured to selectively activate one of the second high side transistor and the second low side transistor based on the second control signal to obtain the output AC signal.

11. The dynamic drive train of any one of claims 1 to 10 wherein:
the inductor is configured to smooth a current waveform of the switched DC signal; and
the at least one capacitor is configured to smooth a voltage waveform of the switched DC signal to obtain the output DC signal.

12. The dynamic drive train of any one of claims 1 to 11, further comprising an electronic control unit operatively connected to the DC-AC controller, the electronic control unit being configured to:
determine and transmit the indication of a required power output to the DC/DC controller; and
determine and transmit the indication of the required inverter output to the DC-AC controller.

13. The dynamic drive train of claim 9, wherein at least one of the first high side transistor and the first low side transistor comprises at least one of: a bipolar junction transistor (BJT), a field-effect transistors (FET), a metal-oxide-semiconductor field-effect transistor (MOSFET), and an insulated gate bipolar transistors (IGBT).

14. The dynamic drive train of claim 9, wherein at least one of the first high side transistor and the first low side transistor comprises a gallium-nitride (GaN) transistor.

15. The dynamic drive train of claim 14, wherein the first high side transistor and the first low side transistor are configured in a top-cooled arrangement with the heat spreader.

16. The dynamic drive train of any one of claims 1 to 15, wherein the cooling system further comprises a heat sink fixed onto a surface of the heat spreader.

17. The dynamic drive train of claim 16, wherein the heat sink is fixed on the surface of the heat spreader using a thermal paste.

18. The dynamic drive train of claim 17, wherein the heat sink is soldered onto a surface of the heat spreader.

19. The dynamic drive train of any one of claims 10 to 18, wherein the first cooling system is configured to maintain the first high side transistor and the first low side transistor at an operating temperature of about 80 degrees Celsius.

20. The dynamic drive train of any one of claims 1 to 17, wherein the first driver is configured to operate at a first driver voltage, and the first half-bridge is configured to operate at a first bridge voltage, the first driver voltage being at least twice the first bridge voltage.

21. The dynamic drive train of any one of claims 1 to 20, wherein the at least one single arm switching power converter comprises a plurality single arm switching power converters configured in phase interleave.

22. The dynamic drive train of any one of claims 1 to 21, wherein the at least one single arm switching power inverter comprises a plurality of single arm switching power inverter configured to provide the output AC signal, the output AC signal being a multi-phase AC signal.

23. The dynamic drive train of any one of claim 21 or 22, wherein a second number of the plurality of single arm switching power inverter is proportional to a first number of the plurality of single arm switching power converter.

24. The dynamic drive train of any one of claims 1 to 23, wherein a first power range of operation of the high frequency DC-DC power converter is equal to a second power range of operation of the DC-AC inverter.

25. The dynamic drive train of any one of claims 1 to 24, wherein the high frequency DC-DC power converter is configured to operate at frequencies between 500 kHz and 100 MHz.

26. The dynamic drive train of any one of claims 1 to 25, wherein high frequency DC-DC power converter is configured to operate at a power range between 250 W to 5 kW.

27. The dynamic drive train of any one of claims 1 to 26, further comprising:
a first set of capacitors electrically connected to the first DC bus and to the half-bridge in the DC-DC power converter; and
a second set of capacitors electrically connected to the first set of capacitors and the half-bridge, wherein the first set of capacitors and the second set of capacitors are configured to smooth transients in the input DC signal.

28. The dynamic drive train of any one of claims 1 to 27, wherein the dynamic drive train is implemented on at least one printed circuit board (PCB).
